(19) United States
(12) Patent Application Publication
(10) Pub. No.: US 2003/0107994 A1
(43) Pub. Date: Jun. 12, 2003

(54) Communications network

(76) Inventors: Richard J Jacobs, Ipswich (GB); Sylvie F Brunelle, Croissy-Sur-Seine (FR)

Correspondence Address: Nixon & Vanderhye, 8th Floor, 1100 North Glebe Road, Arlington, VA, 22201-4714, US

(21) Appl. No.: 10/275,292

(22) PCT Filed: May 15, 2001
(86) PCT No.: PCT/GB01/02138

(30) Foreign Application Priority Data
May 18, 2000 (EP) 00304212.4

(51) Int. Cl. G01R 31/08

(52) U.S. Cl. 370/235; 370/351

(57) ABSTRACT

In a communications network, under conditions of congestion, a congestion field is set by a router in a packet conforming to a connectionless transport protocol. Control packets are transmitted back to the data sender from the data receiver to provide a return channel for the congestion notification.

The present invention relates to communications network, and in particular to a network carrying packet traffic.

In a network such as the Internet carrying packet traffic and using best-effort routing protocols, the performance of the network depends strongly on the loading of the network. When the network is heavily loaded and individual routers are experiencing congestion, then packets may be delayed or lost altogether. Two types of traffic may be distinguished in terms of their response to network congestion. “Elastic” traffic responds to congestion by reducing the demands placed on the network, typically by reducing the packet transmission rate at the source. This type of response is typical of traffic using a connection-oriented transport layer protocol such as TCP (transport control protocol). TCP allows for transmission rates to be adjusted using a congestion window. The second transport type is termed “inelastic” and, by contrast, does not decrease network demand in response to congestion, and may even increase demand in such conditions. Such behaviour is typical of streamed audio/visual traffic using a connectionless transport layer protocol such as UDP (user datagram protocol) or RTP (real time transfer protocol).

According to a first aspect of the present invention, there is provided a method of operating a communications network comprising

a) transmitting packets conforming to a connectionless transport protocol from at least one data source via one or more packet routers to a data receiver;

b) when congestion is detected at a router, then setting a congestion notification field in at least some of the said packets passing through the router;

c) in response to the receipt of one of the said packets including the congestion notification field at the data receiver, outputting a control packet addressed to the data source and including a congestion notification;

d) at the data source, in response to the congestion notification contained in the said control packet, reducing the loading network resources by the said data source.

It has previously been proposed to increase the responsiveness of “elastic” traffic using connection-oriented transport protocols such as TCP by writing a explicit congestion notification (ECN) bit in some packet headers of traffic passing through a router when the first onset of congestion in that router is detected. This approach relied upon the fact that in connection-oriented protocols an acknowledgement signal is returned from the receiver to the data source and this provided a channel to take the congestion notification to the data source. In connectionless transport protocols, by contrast, no such return channel exists. The present inventors have found however that the writing of congestion notification by the router in onwards traffic can provide an effective and efficient method of controlling the response of connectionless traffic, through the use of an appropriate control signal that is returned to the data source when the congestion notification is received.

The step of reducing the loading of network resources by the data source may be carried out directly and automatically by the data source in response to the congestion notification. Alternatively a price-based control mechanism may be used. For example, an increased cost may be payable for continued transmission at a given rate when a congestion notification has been received. In response to the notification, data senders will in general reduce their transmission rate to avoid the additional cost, but some data senders may choose to maintain the transmission rate and to pay the additional cost.

Preferably the control packet conforms to the message format of a bandwidth-limited control protocol, and a constraint applied to the signalling bandwidth available to other packet confirming to the said bandwidth-limited control protocol is not applied in respect of the said control packets containing the congestion notification.

It is found to be particularly advantageous to use for the control signal carrying congestion notification an existing control protocol such as RTCP (RTP control protocol). Conventionally, such control protocols have been used to communicate time-averaged statistics, such as the percentage of packets lost and the level of jitter in a received data stream, and the protocol has been assigned a limited proportion of the network bandwidth in order to prevent the control signalling having an adverse affect on the performance of the primary data stream. The present inventors have realized however that this protocol can be used none the less for the return channel of the congestion notification scheme by removing from the packets used for congestion notification the constraints on bandwidth but applied to all other packets. For example, the bandwidth limitation may be effected by only allowing a receiver to output a control packet once very five seconds. In the case of packets used in accordance with the invention to signal congestion the receiver is enabled to transmit the control packet immediately, without waiting for the expiry of the five second interval.

Preferably the method includes a step carried on the initialisation of a data session during which participants in a session indicate whether they are capable of responding to congestion notification. Participants that are ECN-capable may act either as receivers which signal back receipt of a notification, or as senders that respond to receipt of a signal from a receiver. Preferably the will only marks with a congestion notification packets that are from ECN-capable participants.

This preferred approach to implementing the invention provides the data source with information on the capabilities of the data receiver in the initialisation phase, so that the data source is able to pass that information on to the or each router in the path to the data receiver.

The invention also encompasses data routers and data terminals adapted for use in the method of the first aspect.

Systems embodying the present invention will now be described in further detail with reference to the accompanying drawings in which:

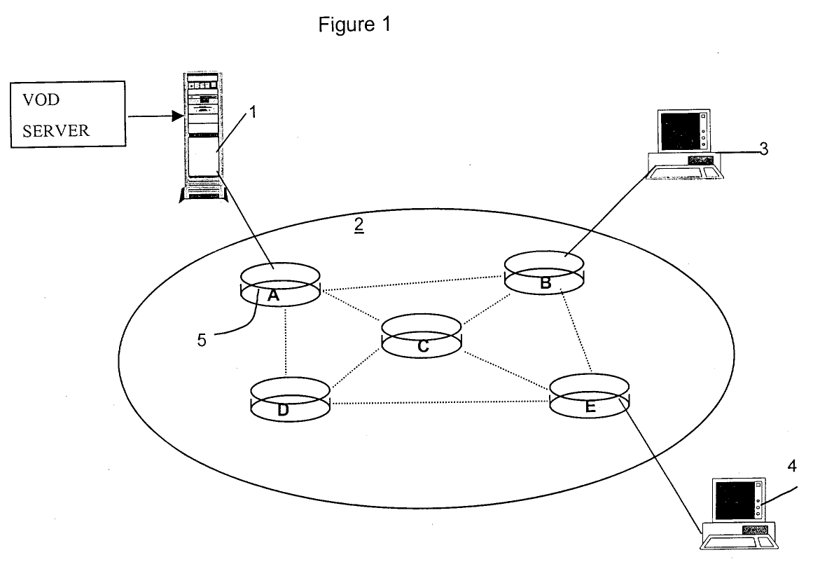

FIG. 1 is a schematic of a network embodying the invention;

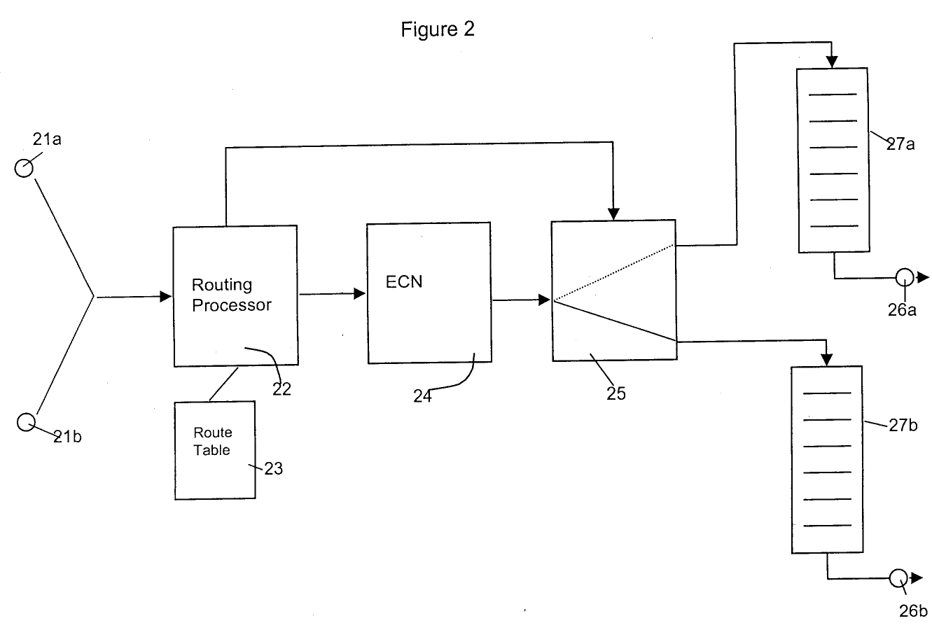

FIG. 2 is a diagram showing the router of FIG. 1;

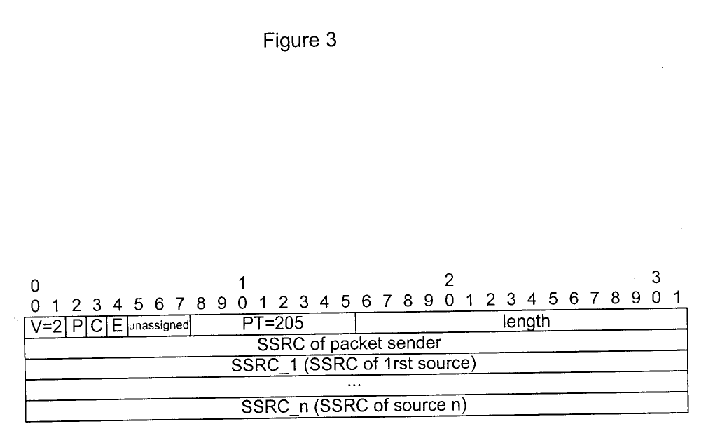

FIG. 3 is a diagram showing bit positions in a control packet;

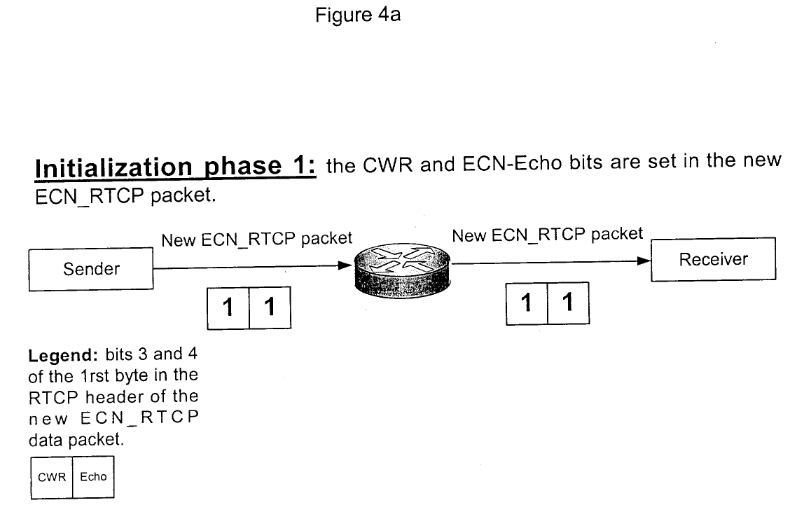

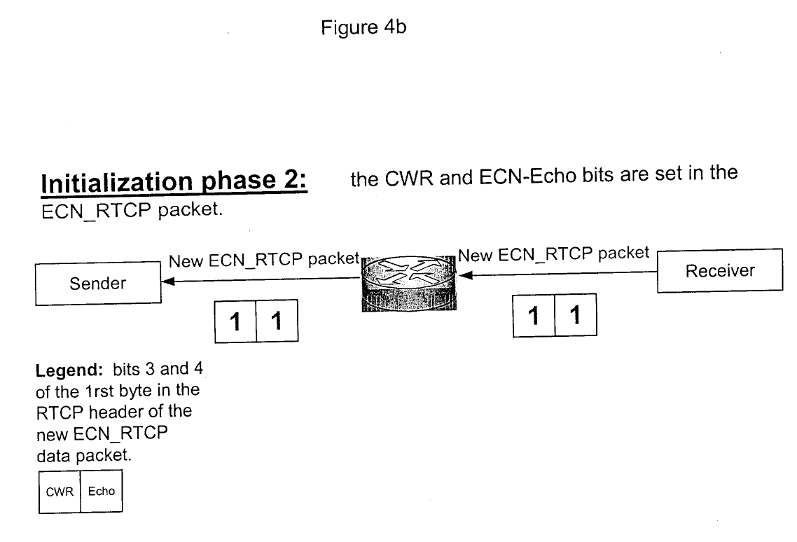

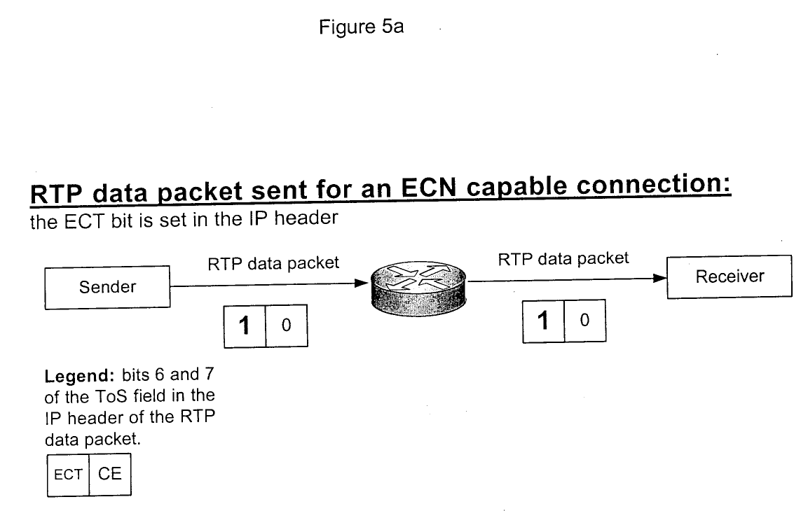

FIGS. 4a and 4b are diagrams showing the transmission of control packets in an initialisation phase; and

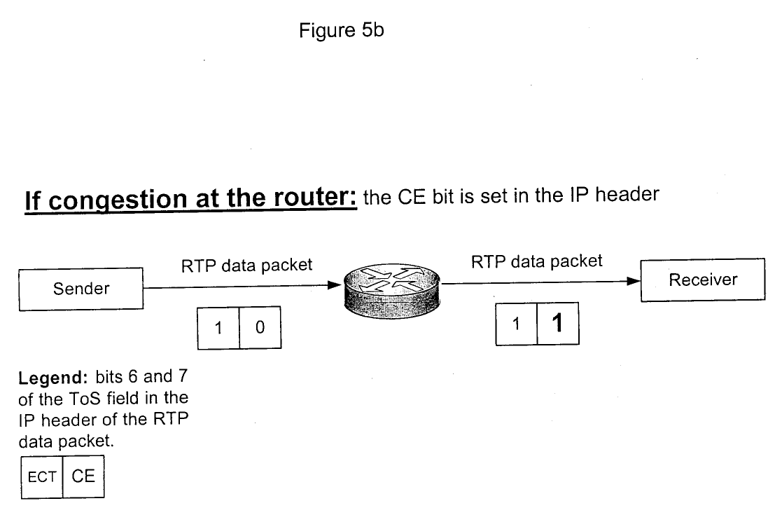

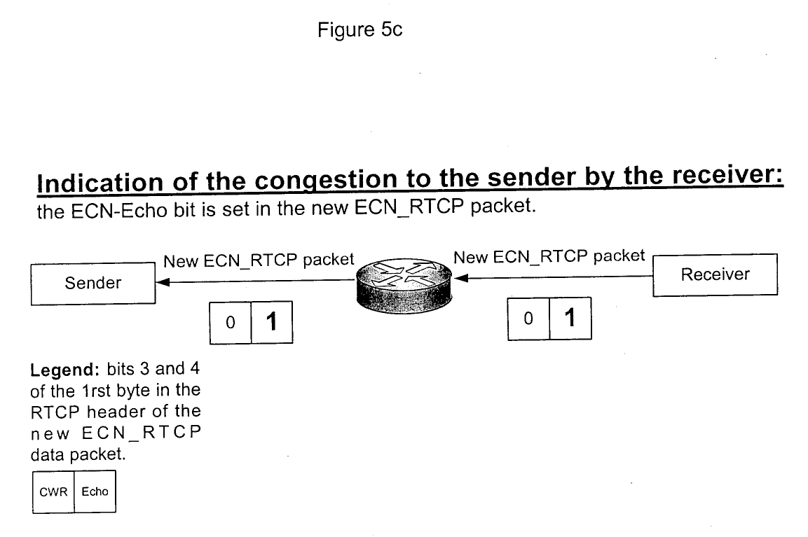

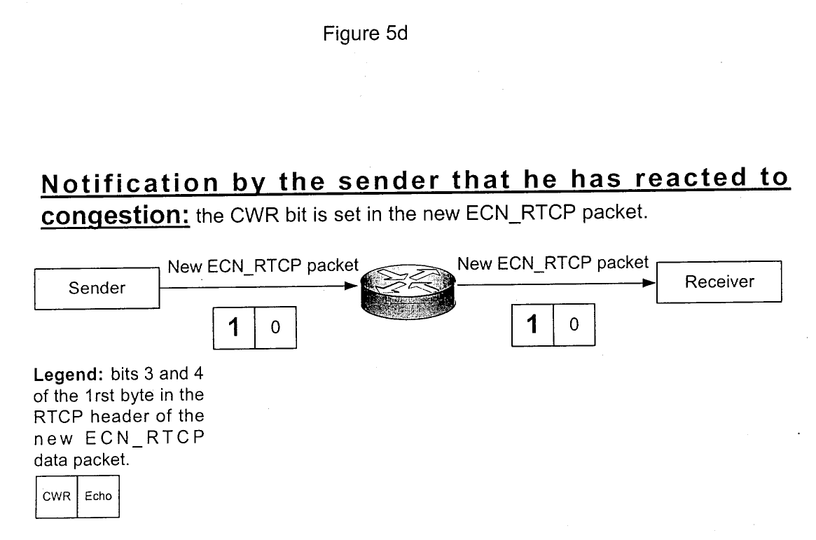

FIGS. 5a to 5d are diagrams showing the transmission of data and control packets subsequent to the initialisation phase.

A data communication system comprises a data server 1 connected via a packet network 2 to customer terminals 3, 4. In this example, the packet network is the public Internet and includes a number of Internet protocol routers 5A-5E.

The data output by the data server 1 comprises streamed multimedia data source, in this example, from a video-on-demand (VOD) server. At the customer terminals 3, 4 the multimedia content encoded in the data is replayed by an appropriate client application, such as, for example, a Realplayer client, ™ a Windowsmedia Player™ or an Apple QuickTime client™.

Data is communicated from the data server 1 to the customer terminals 3, 4 using a connectionless transport-layer protocol. As a result, within the transport-layer, the data server 1 does not receive direct acknowledgement for the receipt of packets by the customer terminals 3, 4, nor is the data server 1 directly aware whether the packets reached their intended destinations. Specifically, the protocols used in the transport-layer, in this example, are UDP (user datagram protocol) with RTP (real-time transport protocol) at the application layer. RTP runs on top of UDP. RTP provides services including time stamps, sequence numbers, payload types, and source identification that are used by multimedia applications in transmitting and reconstituting the multimedia signals.

FIG. 2 shows schematically the architecture of a router for use in the network of FIG. 1. In the router, incoming packets are received at ports 21A, 21B. The packets pass through a routing processor stage 22 that reads the packet headers to determine if they are addressed to the network (if any) local to the router. When the packets are not so-addressed, but are transit packets destined for another network, then routing processor 22 determines from a routing table 23 the address of the next router to which the packet should be directed. In these respects, the functioning of the routing processor and of the routing table 23 are generally conventional. As is well known, there are a number of mechanisms by which the routing table 23 may be updated, depending on whether the router employs dynamic routing or static routing. The packet also passes through an (ECN) stage which, in the manner described in further detail below, may write appropriate values in congestion notification bits contained in header fields of the packet. The packet is subsequently directed via a switch 25 to one or other of the output ports 26A, 26B of the router and from the output ports on to a respective link of the network. Each output port 26A, 26B has associated with it a respective FIFO (first in first out) buffer 27A, 27B. Packets are queued in the respective buffer for transmission from the output port on to the network link. Under conditions of congestion, for example as a result of heavy loading of the respective link, the buffer may be filled to overflowing. In this case, packets are dropped, that is to say they are discarded and not transmitted onwards. In order to reduce the likelihood of this occurring, and the consequent degradation in performance as a result of packet loss, each buffer has associated with it a respective threshold level, for example set to mark when the buffer is full to 70% of its capacity. When the threshold level is reached, the congestion notification mechanism is triggered. The appropriate bit in the packet headers for packets passing through the relevant output buffer are marked to indicate that congestion has occurred. As is described more fully below, when a packet thus marked is subsequently received at the destination address, the respective customer terminal reads the value from the congestion notification field and generates a control message that is transmitted back to the data sender. In response, the data sender reduces the rate of flow of data in the relevant data stream, thereby correspondingly reducing the loading of the congested router and network link. In practice, the buffer thresholds, and the ECN stage may be implemented as software modules running on a common processor with the routing processors. A running total may be maintained of number of packets directed to a given buffer, and the number of packets output or dropped from the buffer to provide a measure of the extent to which the buffer is filled, for comparison with the predetermined threshold level.

In the present implementation, the channel for initial notification when participants in a data session are capable of responding to ECN notifications, the channel for notifying the data sender when subsequently a congestion notification is received at one of the data receivers, and the channel for notifying the data receiver that the sender has received a receiver notification, is provided by a new message type defined for the RTCP protocol. FIG. 3 shows the preferred format of the new message type, termed the ECN_RTCP message. This packet comprises at least 64 bits, 32 bits for the first line and 32 bits for the SSRC of the packet sender. In the case of ECN_RTCP messages sent by the receiver to indicate to one or more data senders that it has received a congestion notification, that is an ECN echo message, the packet includes at least a further 32 bits for at least one source SSRC. In a multicast system with several data senders, a single echo message can then notify several sources. Bit positions 8 to 15 comprise a payload type field and are set to a new value of 205 that identifies the message as being an ECN_RTCP message. Bit 4 is the ECN-echo flag, ie the flag that is set by the data receiver when an ECN notification has been received. Bit 3 functions as a CWR (congestion window reduced) flag, i.e. the flag that is set by the receiver when an ECN-Echo flag is received.

In operation, during an initialisation phase, each participant that is ECN-enabled sends an ECN_RTCP message at the beginning of the data session, or when it joins an ongoing session. This message has bits 3 and 4 set in order to indicate that the sender of the message is ECN_RTCP capable. FIG. 4a shows the transmission of an initialisation message by the sender, and FIG. 4b shows the transmission of an initialisation message by the data receiver. Normally, either the ECN echo bit only is set (by the receiver on receipt of the congestion notification) or the CWR bit only is set (by the data sender to indicate that the sender has responded to the notification of congestion). Thus the setting of both bits is recognized as a special initialisation message indicating that the session participant is ECN_RTP capable. In addition to this use of bits 3 and 4 of the RTCP header, bits 7 and 6 of the IP header are used as flags respectively for CE (congestion experience), ECT (ECN capable transport). Assuming, for example, that both of the customer terminals and the VOD server of FIG. 1 are RTP_ECN capable, and that at least one of the 15 routers, for example router A is RT_ECN capable, then the data sender sets the ECT bit in the IP header in RTP data packets sent to the customer terminals. This is shown schematically in FIG. 5a. Subsequently, if router A experiences congestion, then, in the data flows directed to the customer terminals, the router sets the CE bit in some randomly chosen RTP data packets from the data stream before forwarding them to the customer terminals. This is illustrated in FIG. 5b. The receiver receives the RTP packet, and, on reading the CE bit, knows that there is congestion along the data path. To signal this fact to the data source, the receiver then generates an ECN_RTCP message with the ECN-echo flag (bit 4) set, as shown in FIG. 5c. In this ECN_RTCP message, the receiver lists all the SSRCs of the sources whose packets have been received marked with the CE bit. Such an ECN_RTCP packet differs from other RTCP packets in that the PT (payload type) field has the value 205, bits 3 and 4 are respectively CWR and ECN-echo flags, the ECN-echo flag is set, bits 5, 6 and 7 are unassigned, and the SSRCs list indicates the sources whose packets have been received marked by the receiver. The length field indicates how many SSRCs are listed in the SSRC list.

Subsequently, as shown in FIG. 5d, the source, that is the data sender, responds to such a packet in order to indicate to the receiver that it has received and reacted to the congestion notification. To do this it generates an ECN_RTCP packet which lists the SSRCs of all the participants who sent it a congestion notification. FIG. 5b shows the format of the ECN_RTCP packet sent in this case.

It is a feature of RTCP signalling that it is designed to limit RTCP traffic to 5% of the session bandwidth. For example, if a data sender is video at a rate of 2 Mbps, then RTCP is designed to limit its traffic to 5% of 2 Mbps, or 100 Kbps, allowing 75% of this rate for the receivers and the remaining 25% of the rate to the sender's RTCP traffic. The rate for an individual receiver's RTCP traffic is then equal to the amount allocated to all the receivers, divided by the number of receivers participating in the session. Typically, the bandwidth limitation is enforced by the receiver dividing the RTCP packet size by its allocated rate to determine a fixed period which must lapse between each RTCP transmission from the receiver. For example, the receiver might be limited to one transmission every five seconds. In implementing the system of the present invention, the participants in the session are all programmed to exclude ECN_RTCP messages from the bandwidth limits applied to other RTCP messages. Accordingly, an ECN_RTCP message may be sent by the receiver immediately upon receipt of an ECN notification, without the receiver having to wait a fixed period, eg of five seconds, before transmission.

1. A method of operating a communications network comprising
a) transmitting packets conforming to a connectionless transport protocol from at least one data source via one or more packet routers to a data receiver
b) when congestion is detected at a router, then setting a congestion notification field in at least some of the said packets passing through the router;
c) in response to the receipt of one of the said packets including the congestion notification field at the data receiver, outputting a control packet addressed to the data source and including a congestion notification;
d) at the data source, in response to the congestion notification contained in the said control packet, reducing the loading network resources by the said data source.

2. A method according to claim 1, in which the control packet conforms to the message format of bandwidth-limited control protocol, and in which a constraint applied to the signalling bandwidth available to other packets conforming to the bandwidth-limited control protocol is not applied in respect of the said control packets containing the congestion notification.

3. A method according to claim 1 or 2, in which the connectionless transport protocol is RTP (real-time transport protocol).

4. A method according to claim any one of the preceding claims in which the bandwidth-limited control Protocol is RTCP (RTP control protocol).

5. A method according to any one of the preceding claims, including a step carried out on the initialisation of a data session of sending from participants in the data session an indication whether the respective participant is capable of responding to a congestion notification, and in which the router carries out the step of setting a congestion notification field only for packets from a data sender that has previously sent notification that it is capable of responding.

6. A packet router for use in a communication network, the packet router comprising
a) a data input arranged to receive packets conforming to a connectionless transport protocol
b) means for determining a destination for onwards transmission of transit packets received at the data input
c) a data output arranged to output packets conforming to the connectionless transport protocol
d) means for detecting congestion and
e) means responsive to the said means for detecting arranged to set a congestion notification field in a transit packet conforming to the said connectionless transport protocol prior to passing the said packet to the data output.
